(19) United States
(12) Patent Application Publication
(10) Pub. No.: US 2009/0146847 A1
(43) Pub. Date: Jun. 11, 2009

(54) System and method for using human recognizable content to communicate with electronic devices

(76) Inventors: Jason E. Barkeloo, Cincinnati, OH (US); Bradley Louis Chapman, Columbus, OH (US); Paul David Breneman, Plain City, OH (US); David A. Krauth, Manchester, NH (US)

Correspondence Address: TAFT, STETTINIUS & HOLLISTER LLP, SUITE 1800, 425 WALNUT STREET, CINCINNATI, OH, 45202-3957, US

(21) Appl. No.: 12/313,433

(22) Filed: Nov. 20, 2008

Related U.S. Application Data
(60) Provisional application No. 60/989,465, filed on Nov. 21, 2007.

(51) Int. Cl. H03K 17/94; G05B 23/02

(52) U.S. Cl. 341/20; 340/3.1; 340/664

(57) ABSTRACT

A system for utilizing human-recognizable material to interact with digital content may include human-recognizable content, an electric field generating device adapted to generate an electric field, an electric field emitting device adjacent to the human-recognizable content and in electrical communication with the electric field generating device, the electric field emitting device adapted to emit the electric field, and a host device configured to output digital content associated with the human-recognizable content. The host device may be in electrical communication with the electric field generating device. The host device may receive one or more instructions from the electric field generating device.

### CROSS-REFERENCE TO RELATED APPLICATIONS

This application claims the benefit of U.S. Provisional Application Ser. No. 60/989,465, entitled “SYSTEM AND METHOD FOR USING HUMAN RECOGNIZABLE CONTENT TO COMMUNICATE WITH ELECTRONIC DEVICES,” filed on Nov. 21, 2007, the disclosure of which is incorporated herein by reference.

### FIELD OF THE INVENTION

The present invention is related generally to a system and method for utilizing human-recognizable material to communicate with electronic devices. Specifically, the system and method allows communication with and/or access to electronic devices and/or content by bringing a finger or other object near the human recognizable material.

### BACKGROUND OF THE INVENTION

Recently, articles with human recognizable content have been fitted to connect electronically with computers and other media storage devices to retrieve and display digital content. The human recognizable material with associated means to connect electronically to digital content may be called “interactive hybrid printed material”, or IHPM. The IHPM technology enables, in one aspect, a reader to use a finger to touch the pictures and words on the regular printed ink and paper page and retrieve digital content from a computer or other storage device. The interactive hybrid printed material has been fitted with devices such as membrane switches, mechanical switches, or touch sensitivity pads adjacent the printed material to associate the human-recognizable material with the digital material. A user interacting with the printed material may press and/or actuate a switch adjacent the printed material or graphics to obtain digital content from a connected host device. Examples of such IHPMs are described in U.S. Pat. Nos. 5,624,265, 5,757,304, 5,749,735, 5,763,112, 5,788,507, 5,839,905, 5,911,582, 5,957,695, 6,327,459 and 6,650,867, the disclosures of which are incorporated by reference.

However, mechanical switches and pads may deteriorate and become less dependable over time. Mechanical switches and pads require physical displacement and/or pressure, and so are susceptible to environmental factors and characteristics such as moisture, fatigue wear, contact bounce, corrosion, and arcing. Furthermore, switches or pads require direct contact by the user so that effective protective coverings that protect the switch while still allowing direct contact by the user become difficult, if not impossible, to design. Additionally, switches or pads that require direct contact cannot be designed to sense the presence of a non-touching object a distance above the pad surface and communicate information about the distance between the object and the pad.

Accordingly, it is desirable to have an IHPM and method for using it where the IHPM has a more robust interface device that does not depend on mechanical movement. It is desirable to have an IHPM with an associated device that senses an object near the device, so the user does not have to touch a pad or switch to determine choice of digital content. Additionally, it is desirable to have an IHPM with an associated device that emits an electric field usable to detect the presence of an object within the electric field. Further, is desirable to have an IHPM with pads that are easily shielded from moisture or the environment. Embodiments of the present invention provide systems having human recognizable material linked to digital content with a device that does not require direct touch to activate.

### SUMMARY OF THE INVENTION

Embodiments described herein provide a system for using human-recognizable content to communicate with electronic devices.

In a first aspect, a system for utilizing human-recognizable material to interact with digital content may include human-recognizable content, an electric field generating device adapted to generate an electric field, an electric field emitting device adjacent to the human-recognizable content and in electrical communication with the electric field generating device, the electric field emitting device adapted to emit the electric field, and a host device configured to output digital content associated with the human-recognizable content. The host device may be in electrical communication with the electric field generating device. The host device may receive one or more instructions from the electric field generating device.

In one embodiment of the first aspect, the system further includes a non-conductive cover component positioned adjacent to the electric field emitting device. In another embodiment, the human-recognizable content includes a first human-recognizable content associated with a first digital content and a second human-recognizable content associated with a second digital content. The first human-recognizable content is replaced by the second human-recognizable content and the host device may be instructed to output the second digital content.

In another embodiment of the first aspect, the human-recognizable content includes documents, magazines, newspapers, brochures, articles, manuals, books, publications and/or periodicals.

In yet another embodiment of the first aspect, the electric field emitting device is adapted to sense an object adjacent to the electric field emitting device. In another embodiment, the electric field generating device senses a distance from an object to the electric field emitting device. In another embodiment, the electric field generating device and the electric field emitting device may operate as one component. In another embodiment, the electric field generating device and the electric field emitting device may be enclosed within substantially the same physical component.

In even yet another embodiment of the first aspect, the electric field generating device is detachably coupled to the human-recognizable content. In another embodiment, the electric field emitting device is integrated within the human-recognizable content. In another embodiment, the human-recognizable content includes a front cover and/or a back cover. In another embodiment, the electric field emitting device is integrated within the front cover and/or the back cover of the human-recognizable content.

In yet another embodiment of the first aspect, the electric field generating device generates an electric current that creates the electric field. The electric field emitting device is further adapted to sense a change in the electric current to determine that an object is near the electric field emitting device. The host device outputs digital content based, at least in part, on the sensed change in the electric current.

In a second aspect, a method of accessing digital content may include the steps of: (a) providing human-recognizable content and one or more digital content associated therewith; (b) providing one or more electric field generating devices and one or more electric field emitting devices; (c) generating, by the one or more electric field generating devices, one or more electric fields; (d) emitting, by the one or more electric field emitting devices, the one or more electric fields adjacent the one or more human recognizable content; (e) placing an object substantially within at least one of one or more electric fields; (f) recognizing, by the electric field emitting device, which electric fields are near the placed object; and (g) retrieving one or more digital content from a database of digital content based, at least in part, on which electric fields are near the placed object.

In one embodiment of the second aspect, the method further includes the steps of: (h) providing a second human-recognizable content and one or more digital content associated therewith; (i) replacing the human-recognizable content with the second human-recognizable content; (j) placing the object substantially within at least one of one or more electric fields; (k) recognizing, by the electric field emitting device, which electric fields are near the placed object; and (l) retrieving one or more digital content from a second database of digital content based, at least in part, on which electric fields are near the placed object.

In another embodiment of the second aspect, the object is a human finger, a human hand and/or an input device. In yet another embodiment, the human-recognizable content includes documents, magazines, newspapers, brochures, articles, manuals, books, publications and/or periodicals.

In a third aspect, a system for utilizing human-recognizable material to interact with digital content may include a panel adapted to receive human-recognizable content thereon, and a plurality of sensing pads in electrical communication with the panel. The plurality of sensing pads are coupled to the panel. At least one sensing pad is configured to indicate a page number of the human-recognizable content, and at least one sensing pad is configured to indicate a digital content associated with the human-recognizable content.

In one embodiment of the third aspect, the plurality of sensing pads are further configured to sense an object near at least one of the sensing pads. In another embodiment, the system further includes a cover component located between the panel and the human-recognizable content such that the cover component does not interfere with the operation of the plurality of sensing pads.

In another embodiment of the third aspect, the plurality of sensing pads are arranged on the panel to substantially form a rectangular pattern having a plurality of rows and a plurality of columns. The sensing pads configured to indicate a page number of the human-recognizable content are arranged along at least one row or column running along an edge of the panel.

From the foregoing disclosure and the following detailed description of various preferred embodiments it will be apparent to those skilled in the art that the present invention provides a significant advance in the art of interactive printed material interface systems and methods. Additional features and advantages of various preferred embodiments will be better understood in view of the detailed description provided below.

### BRIEF DESCRIPTION OF THE DRAWINGS

The present invention will be understood and appreciated more fully from the detailed description in conjunction with the following drawings in which:

FIG. 1 is an illustration of printed matter with an associated electric field generating circuit according to one embodiment of the present invention.

FIG. 2 is a schematic illustration of a panel having electrodes that may sense proximity of an object.

FIG. 3 is a schematic illustration of traces of a board that support a panel having electrodes that sense proximity of an object.

FIG. 4 is an illustration of another embodiment for holding human-recognizable content adjacent a panel, shown in exploded view.

FIG. 5 is an illustration of yet another embodiment of a portion of a form-factor for holding human-recognizable content.

FIG. 6 is a schematic representation of an arrangement of sensing pads.

FIG. 7 is a schematic representation of an exemplary arrangement of sensing pads.

FIG. 8 is a schematic representation of a method of using human-recognizable content interfacing with electronic devices to perform a commercial transaction.

### DETAILED DESCRIPTION

It will be apparent to those skilled in the art that many uses and variations are possible for the systems and methods disclosed herein. The following detailed discussion of various exemplary embodiments will illustrate the general principles of the invention. Other embodiments will be apparent to those skilled in the art given the benefit of this disclosure.

In accordance with various exemplary embodiments of the present invention, interactive hybrid printed material having an associated device that senses the presence of an object near the device is presented. The device that senses the presence of the object may include an electric field emitting device placed near particular print or graphics. The electric field emitting device may electrically communicate with an electric field generating device. The electric field generating device may sense the proximity of objects moving into the vicinity of the electric field emitted from the electric field emitting device. The system may allow a user to bring a finger or object near the print, graphics, or other human recognizable content to communicate with an electronic device.

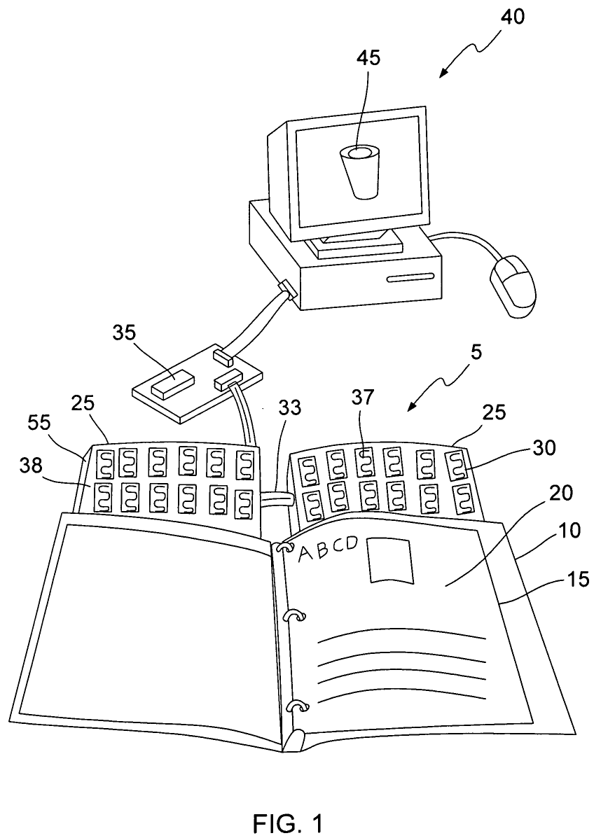

Referring now to the Figures, in which like numerals indicate like elements, FIG. 1 discloses a system for utilizing human-recognizable material to interact with digital content, IHPM 5, according to an embodiment of the present invention. In the embodiment, a notebook 10, to hold and secure printed material, may contain at least one page 15 of human recognizable material, or content 20, such as printed matter, graphics, Braille, an attached sound-producing device, or the like. A person using hearing, touch, smell, or sight may sense content 20. FIG. 1 further displays a panel 25 containing at least one, and perhaps a plurality of electric field-emitting devices in the form of sensing pads 30. Panel 25 may be inserted into a pouch on a cover of notebook 10. A second panel 25 may be placed within the other cover of notebook 10, and these panels may link together through an electrically conducting connection strip 33. Each sensing pad 30 comprises at least one, and perhaps a plurality of, electrodes 37 that emit an electrical field usable to sense the proximity of an object, as will be seen. A cover 38 to protect sensing pads 30 from the environment, such as a film of plastic, nylon, rubber, glass, or the like, may cover sensing pads 30 to shield them from the environment. Cover 38 may be an electrical insulating material so that electrodes 37 of sensing pads 30 have non-direct electrical communication instead of a direct short path through a conductive material. Cover 38 may be a plate, or a thin non-conductive coating.

Electrodes 37 of sensing pads 30 on panel 25 are in electrical communication with an electric field generating device, such as an E-Field Integrated Circuit (IC) 35. E-Field IC 35 may be, for example, a model MC9S08SH8CDTE, MC34940, or MC33794 IC available through Freescale Semiconductor in Austin, Tex., or similar micro devices commercially available. E-Field IC 35 generates a sinusoidal electric current that creates the electric field around electrodes 37 of sensing pads 30.

E-Field IC 35 communicates with a host device 40 containing digital content 45 that may be rendered on an image display of host device 40. E-Field IC 35 may communicate with host device 40 by direct connection (such as USB, for example), or by a wireless signal (such as a radio signal or a laser signal, for example). Host device 40 may be, for example, a computer, cell phone, mobile phone, CD player, DVD player, personal digital assistant, television, iPod® portable media player, or any electric device capable of rendering digital content 45 in human-recognizable format. Host device 40 may even be an entire system communicating with other devices via internet, Bluetooth, laser, or other applications. For example, host device 40 may send a signal such as an e-mail, an instant message, or a commercial transaction to another electronic device based on information received from E-Field IC 35. As described herein “accessing digital content” may include sending and receiving e-mails, instant messages, internet communications, commercial transactions, operating remote machinery, or the like. “Digital content” may include the messages, communications, information stored electronically, information obtained from a network (such as the Internet) electronically, information on business transactions, communications from remote machinery, and the like.

In one embodiment, E-Field IC 35 fits on a circuit board associated with an interactive reader. Interactive reader may have a housing created from plastic and may attach to a connector interface located on a suitable carrier of human recognizable content such as a magazine, a book, a softbound publication, or the like. An electrical connector affixes to the printed circuit board carrying E-Field IC 35. A panel made of paper, plastic, film, polymer or other similar material that may have sensing pads 30 installed on the panel is associated with one or both covers of the carrier and is in electrical communication with the connector interface. The panel may be made flexible to be readily usable with a softbound publication such as those commonly mailed in standard postal service. A magazine cover may, for example, contain a flexible panel. Where both front and rear covers of a magazine (or any suitable carrier) contain flexible panels, the flexible panels may electrically communicate with each other in manners described herein.

A suitable electronic coat protector film may cover an outer cover associated with flexible panel. Such a suitable cover may be made of clear plastic, plastic, film, polymer or other similar material.

An upper housing half and a lower housing half, creating an assembled housing, may enclose the printed circuit board carrying IC 35. The halves may be formed of, for example, molded plastic. Upper half may contain an opening through which an electrical connector has electrical communication to connector interface. Upper half may have an extending clip, suitable for clipping assembled housing to the content carrier. Electrical communication may be established by implementing wired and wireless communication methods. For example, to maintain a moisture-tight seal around the printed circuit board carrying IC 35, a wireless method such as Bluetooth or IEEE 802.11x (where x is a, b, g, n, or other IEEE standards), for example. In one embodiment implementing wireless communications, the electrical components including the E-Field IC 35, for example, may be powered by a rechargeable battery located within or external to the IHPM 5.

In another embodiment, the interactive reader may have electrical circuitry allowing E-Field IC 35 to make remote contact with host device to communicate a user's choice of sensor pad. Remote contact may be made with RF waves, Bluetooth, infrared signal, or similar contact methods. Thus, the interactive reader becomes a compact assembly easily detached from one carrier (such as a first magazine) and reattached to another so that a user may use the interactive reader with a number of periodicals with little effort. A publisher of content may, for example, mail out carriers in the form of panel-equipped periodicals that are interchangeable with an interactive reader. Users may use the interactive reader to easily actuate and display digital content available from the publisher. The publisher, in turn, may change or update digital content with each new mailing of a new periodical. For example, when the February version of a particular magazine is mailed, the publisher may desire to remove digital content associated with the January version of the magazine.

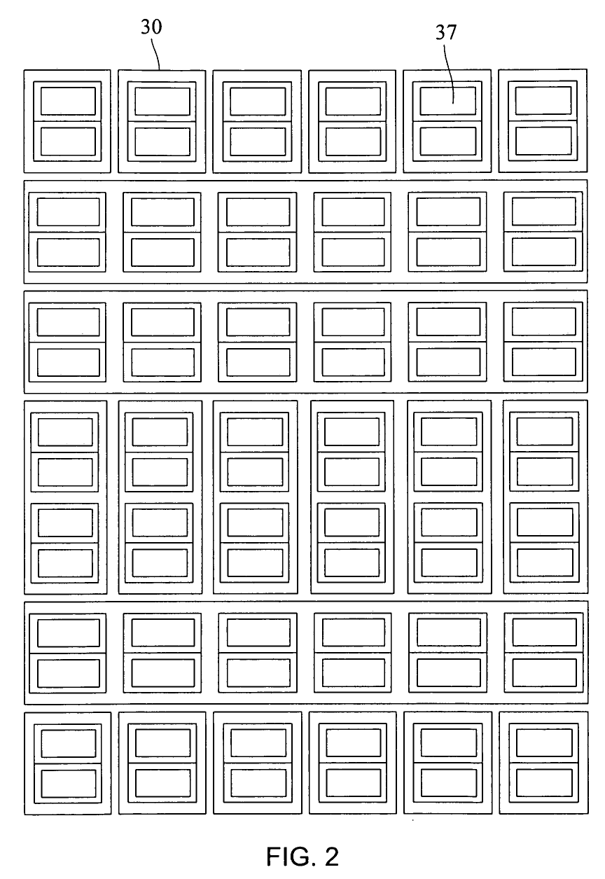

FIG. 2 displays an illustrative schematic example of sensing pads 30 located on panel 25. Sensing pads 30 contain at least one electrode 37. Electrode 37 emits an electric field having an electric field current that may sense presence of an object (such as, but not limited to, a human finger). The object positioned sufficiently near the electric field causes a change in electric field current in the electrode 37 near the object. E-Field IC 35 senses the change in electric field current by measuring a voltage drop across an internal resistance, and sets a level in a pin of E-Field IC 35. E-Field IC 35 thus signals that an object is present near an electrode 37, and may process the information to activate a process based on the information. The process may be to send a signal to host device 40 to display digital content 45. Sensing pads 30 may be large, so that they nearly completely fill a standard 8.5 by 11 inch plate. For example, a six by seven sensing pad pattern is shown in FIG. 2, and this pattern of 42 sensor pads may substantially cover a plate of approximately 8.5 by 11 inches. Thus, a user may select any place on a standard 8.5×11 inch document and contact or come near a sensing pad 30.

More than one electrode 37 may be used within one sensing pad 30. If more than one electrode 37 is used within a sensing pad 30, E-Field IC 35 will measure the change in electric field current of one electrode 37 at a time and set others to ground. E-Field IC 35 then selects a second electrode and completes the measurement process. E-Field IC 35 may thus sense the presence of an object near more than one electrode 37 within one sensing pad 30 if sensing pad 30 is composed of more than one electrode 37. By constructing panel 25 so that each sensing pad 30 each has a coordinate location defined by its set of electrodes 37, a large number of sensing pads may be sensed using a small number of electrodes 37. For example, an E-Field IC 35 capable of sensing nine electrodes may sense the presence of objects near forty-five different sensing pads 30 by assigning a different electrode pair combination to each sensing pad 30. If more than two electrodes 37 are assigned to each sensing pad 30, presence of objects near more than forty-five sensing pads 30 may be sensed.

Sensing pads 30 may be programmed to determine which of multiple sensing pads 30 influenced by an object is closest to the object. For example, if a user places a finger, input device, or other object near a boundary of two sensing pads 30, E-Field IC 35 may determine which sensing pad 30 is most influenced by the presence of the object. The system may then proceed as if the user chose the most influenced sensing pad 30.

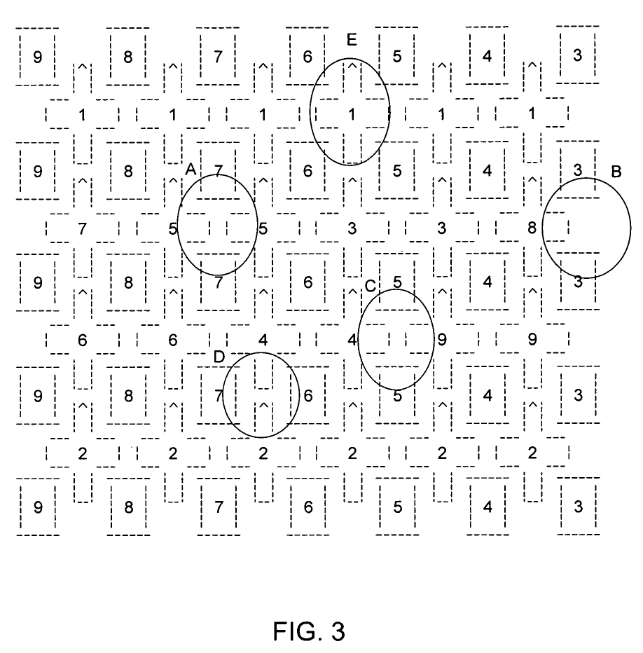

FIG. 3 shows a schematic example of wires 50 in the form of traces on a printed circuit board 55 to connect E-Field IC 35 to electrodes 37 on a panel 25. Electric fields are schematically represented as the areas “A” through “E”. Electrodes 37 may be formed from, for example, copper traces. Sensing pads 30 having electrodes 37 may be placed directly on printed circuit board 55 to create panel 25, or on a separate pad placed over printed circuit board 55 for example. In another exemplary embodiment, one side of printed circuit board 55 may carry panel 25 with sensing pads 30 while the opposite side contains wires 50 to communicate electric signals between E-Field IC 35 and electrodes 37. In yet another embodiment, E-Field IC 35 may itself locate on one side of printed circuit board 55 with wires 50 directing signals to electrodes 37 placed on sensing pads 30 on the opposite side of printed circuit board 55. Great flexibility in location of components will become apparent to one skilled in the art. In one embodiment, the electrical components including the E-Field IC 35, for example, may be powered by a rechargeable battery located within or external to the IHPM 5.

A conductive shield to keep wires from emitting an electric field may cover wires connecting electrodes 37. The conductive shield may be connected to a pin on E-Field IC 35 that sends a buffered signal having the same amplitude and phase of a signal driving the electrode 37 that is emitting the electric field. The conductive shield may be made of, for example, copper, gold, aluminum, solder, or other electrically conductive materials.

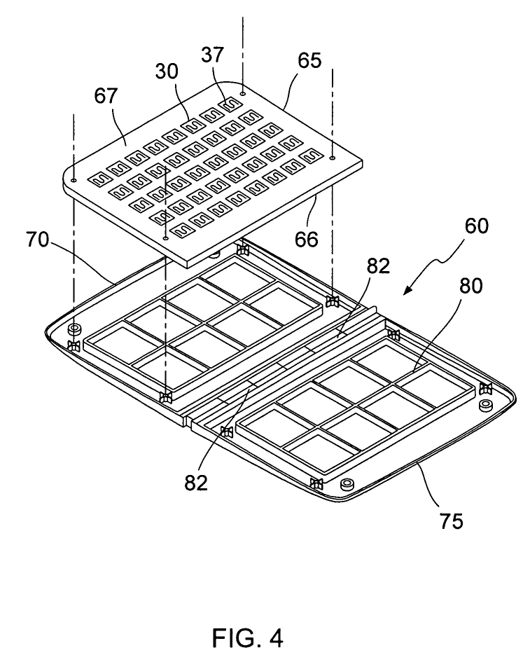

FIG. 4 displays a holder for content 20 called a form-factor 60. Shown in exploded isometric view from form-factor 60 is a combination board 65 that may be, for example, a combination of printed circuit board side 66 on one side and panel side 67 on the opposite side. Form-factor 60 may hold a plurality of combination boards 65 and content 20 (FIG. 1). Combination boards need not be identical, however, only one combination board 65 is shown in FIG. 4 for clarity.

Form-factor 60 has at least two rotatable portions, a left cover 70 and a right cover 75, that may approximate to enclose and/or protect content 20 and combination boards 65. Combination boards 65 may attach to left cover 70 and right cover 75 by, for example, screws or snaps. To increase support and rigidity, left cover 70 and right cover 75 each have ribs 80 rising from a largely planar surface of left cover 70 and right cover 75. Alternatively, standoffs or bosses may replace ribs 80, and combination boards 65 may attach to the standoffs or bosses.

FIG. 4 further shows combination boards 65 with sensing pads 30 having electrodes 37, as described before. E-field IC 35 may reside on a combination board 65 on a printed circuit board side 66 opposite sensing pads 30, while sensing pads 30 reside on panel side 67. E-field IC 35 may communicate electrically with electrodes 37 through traces on combination board 65, and may communicate electrically through printed circuit board side 66 with host device 40 by, for example, wire, Bluetooth, flat cable, laser, or other known wired and wireless ways to transmit electronic information.

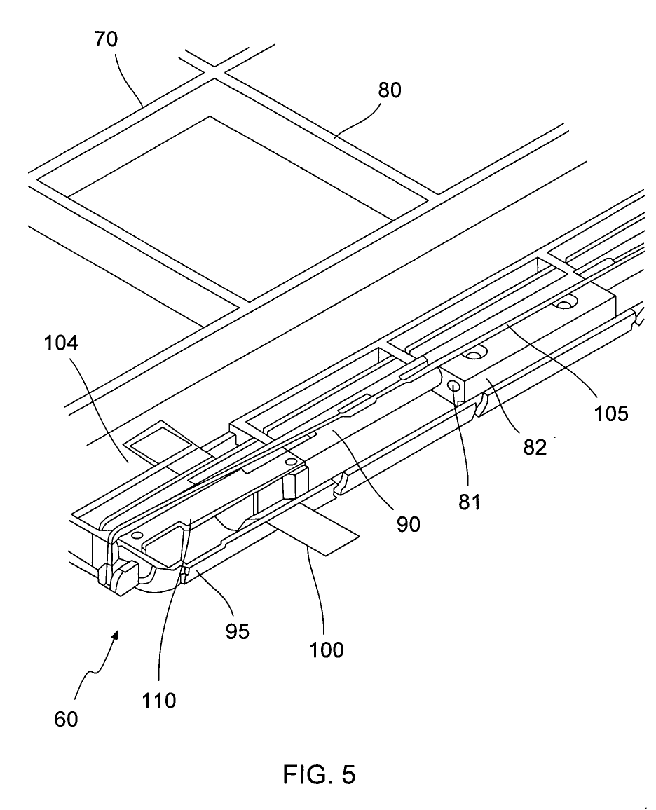

FIG. 5 depicts further details of form factor 60 in a close-up isometric view. The view is taken at the bottom edge in the area in between left cover 70 and right cover 75. Right cover 75 and combination boards 65 are removed for clarity. Spine 82 holds rotatable left cover 70 and right cover 75 by providing through holes 81 through which rods (not shown) or other axial member may be placed. The rod or other axial member may also be assembled within cylindrical cover axis 90. In one embodiment, cylindrical cover axis 90 may snap fit into a boss or protrusion on spine 82, or other assembly methods may occur to designers. Right cover 75 rotatably attaches to spine 82 in a similar manner, so that both right cover 75 and left cover 70 rotate towards and away from each other. A second spine 82 (FIG. 4) also may locate centrally between left cover 70 and right cover 75 to position and restrain right cover 75 and left cover 70.

Spines 82 hold back cover 95 fixed in relationship with spines 82 to protect moving and electronic cables, as will be seen. Back cover 95 may affix to spines 82 with screws or similar coupling means, or one may fashion back cover 95 and spines 82 as a unitary piece, by, for example, injection molding or machining.

Proceeding from one combination board 65 to a second combination board 65 is a cable 100 for transmitting information between combination boards 65. Cable 100 may be flexible so that rotation of right cover 75 and left cover 70 flex, but do not break or strain cable 100. Any number of grooves 104 may be placed into right cover 75, left cover 70, and back cover 95 to locate and guide any number of cables 100 needed. A cable cover 110 holds cable 100 in place, restraining it from traveling into a position where it may be pinched. Back cover 95 protects cable 100, and allows form factor 60 to become an enclosure when left cover 70 and right cover 75 are closed.

A restrainer 105 for pages 15 attaches to back cover 95 at one end, proceeds along the central midline between left cover 70 and right cover 75 and attaches again to back cover 95 at a second end. Restrainer 105 is flexible, and has a hook shape at each end engaging a catch at each end of back cover 95. Restrainer 105 holds pages 15 within form factor 60 near installed combination boards 65 to create an embodiment of interactive hybrid printed material useful for accessing digital content. Pages 15 carrying content 20 content 20 may be loaded within form factor 60 adjacent either or both combination boards 65. Restrainer 105 locks into position over pages 15 to keep pages 15 from falling free of form factor 60.

A person using IHPM 5 may access page 15 and sense human recognizable content 20 by reading, hearing an attached sound device, or feeling Braille text, for example. A person wanting to know more information about content 20 then brings a finger or another object near a picture, certain text, or a designated area on content 20, which brings the object near an electric field emitted from an electrode 37 placed within sensing pad 30. For example, an icon chosen from a library of icons available through Somatic Digital in Cincinnati, Ohio, may mark the designated area on content 20 associated with a particular electric field generated by an electrode 37 positioned under the content 20. Electrode 37 communicates with E-Field IC 35, and E-Field IC 35 determines which sensing pad 30 has been selected utilizing electric field measurements of one or more electrodes 37 associated with sensing pad 30. E-Field IC 35 chooses from a database of digital content 45 the digital content 45 associated with the one or more electrodes 37 within sensing pad 30, and sends a signal to host device 40 to display digital content 45. Digital content 45 is then rendered into human recognizable form by, for example, displaying it on a screen. In the example illustrated in FIG. 1, digital content 45 is displayed on a computer screen in the form of an image of a cup.

Human recognizable content 20 may be changed. For example, one set of documents, such as pages 15 carrying content 20, may be removed from notebook 10 and another substituted. E-Field IC 35 may then be caused to access a different set of instructions to direct the person to new digital content 45 that relates more information on the new set of documents. Accordingly, a user may replace human recognizable content 20 with another set of human recognizable content 20, and E-Field IC 35 may then access different digital content 45 to supplement the new human recognizable content 20.

Various methods may be used to determine which page a user is accessing if content 20 is found on many pages 15, or layers. A user may select two sensing pads 30 in consecutive order to communicate, for example, first the page number the user is accessing, then the portion of the page that the user is accessing.

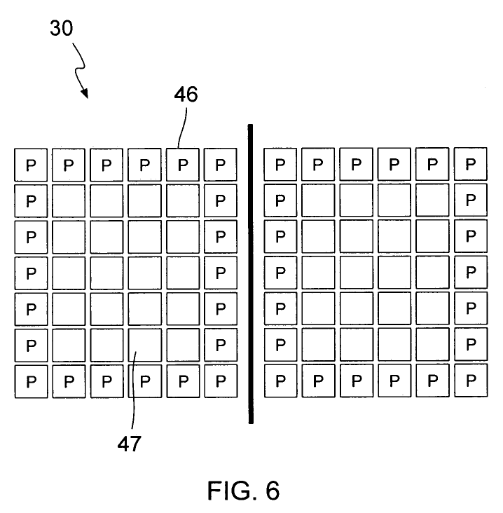

FIG. 6 schematically displays one arrangement of sensing pads 30. The arrangement shows two types of sensing pads 30: sensing pads 30 used to access host device 40 to display or use digital content 45 and sensing pads 30 used to communicate a page face number to E-Field IC 35 and host device 40. In the schematic layout of FIG. 6, the vertical line represents the vertical centerline of a holder for content 20, such as notebook 10 or the like. Squares represent a possible arrangement of sensing pads 30 on a panel 25. Page face indicator pads 46, marked “P” and which are sensing pads 30 used to communicate a page face number, surround content pads 47, used to display digital content 45. Content pads 47, left blank in the schematic illustration of FIG. 6, are sensing pads 30 that may direct the user to certain digital content 45 associated with the content pad 47. In the configuration of FIG. 6, forty-four page face indicator pads 46 and twenty content pads 47 reside on each panel 25. Pages 15 may lie against each panel 25 and may be enumerated with page face numbers. One page face number may label each page face of page 15, for a total of two page faces per page 15, on the opposite sides of page 15. One page face within an insert, such as a book, containing multiple pages 15 may have an icon or other mark aligning within the bounds of a particular page face indicator pad 46. Page 15 may also contain up to twenty icons or other indications of available digital content 45 placed within the bounds of one or more of content pads 47. A user may indicate a page number by choosing a number or icon placed within the bounds of the proper page face indicator pad 46, and indicate desired digital content 45 by choosing an icon placed within the boundary of a content pad 47. A user may turn page 15, reveal the second page face on the opposite side of page 15, and indicate the new page face number by choosing the icon aligned within the bounds of the proper page face indicator pad 46. The new page face number is communicated to E-Field IC 35, and new human recognizable content 20, containing icons or markers directing the user to new digital content 45 are available to the user.

Thus, in the configuration of FIG. 6, forty-four total page faces each bearing up to twenty icons to obtain different digital content 45 are available to the user when the user chooses only one page face indicator icon per page face. If there are two page faces per complete page 15, one on each side of page 15, a total of twenty-two pages 15 of human recognizable content 20 may display icons directing the user to digital content 45. Additional pages may be incorporated if software and/or firmware allows the user to choose more than one page face indicator pad 46 to indicate a single page number. More pages may also be incorporated if more sensor pads 30 are dedicated to become page face indicator pads 46 by, for example, creating a second ring of page face indicator pads 46 inside the first ring. However, the increase of page face indicator pads 46 decreases the number of content pads 47 available to the user.

Since E-Field IC 35 has a finite number of addresses, a configuration of FIG. 6 using more sensing pads 30 to denote page number causes a consequent decrease in sensing pads 30 available for indicators of areas to touch to retrieve digital content 45.

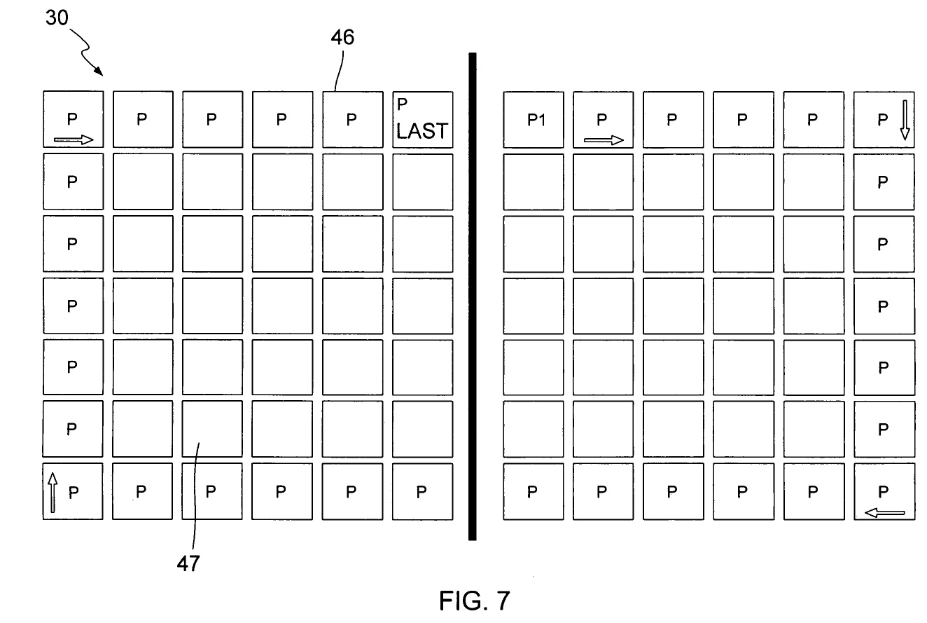

FIG. 7 shows a second embodiment of an arrangement of sensing pads 30 usable to indicate both page face number and digital content available. FIG. 7 shows page face indicator pads 46, denoted P, on the outer edge of both panels 25; however, no page face indicator pads are on the interior sections of panels 25 near the vertical centerline. Pages 15 of content 20 may lie open on the two adjacent panels 25. One page face indicator pad 46 may indicate two adjacent page faces, for example, page face two and page face three. The next page face indicator pad may be assigned to page faces three and four, and so on. Two exceptions occur. The first open page and the last open page may not have an opposite page face, and so only one page face may be associated with page face one and the last page face.

A user of the arrangement of FIG. 7 may open an insert containing pages 15 to page face one and choose the icon placed within the boundaries of the page face indicator 46 associated with page face one. The user may, for example, choose a page face indication icon adjacent the page face indicator pad 46 in the upper left-hand corner of the right hand page face, marked with a “1” in FIG. 7. The page face indicator associated with the first page has only one, instead of two, page faces associated with it. The user may then choose an icon or other mark on page face one associated with a content pad 47 to obtain digital content 45 associated with that content pad 47 for page face one. The user may turn a page 15 to open the insert to display page faces two and three, and select the mark or icon on either one of pages two and three within the boundaries of the page face indicator 46 associated with page faces two and three. The user may enjoy a choice of digital content 45 by selecting an icon associated with a particular content pad 46 for page faces two and three. The user may turn the page to display page faces four and five, and so on. The page face indicator associated with the last page face has only one, instead of two, page faces associated with it, similar to the first page face. The page face indicators may be numbered sequentially as shown in FIG. 7, starting with the page face indicator icon numbered “1” and proceeding clockwise around the outer perimeter of the set of sensing pads 30 shown on FIG. 7. Other numbering schemes will occur to designers.

The FIG. 7 embodiment enables an IHPM 5 to display more digital content than the embodiment of FIG. 6 with an E-Field IC 35 having the same number of addresses. Conversion of page face indicator pads 46 to content pads 47 in the interior of the open pages 15 along the vertical centerline, and assignment of most page face indicator pads 46 to two page faces, instead of one, create the benefit. In the FIG. 7 configuration, each page face indicator pad 46, except the first and last, is assigned two page faces. Therefore, the second page face indicator pad 46 is assigned page faces two and three; the third is assigned page faces three and four, and so on. The exceptions are the first page face indicator pad 46, assigned only the first page face, and the last page face indicator pad 46, assigned to the last page face. If, as in FIG. 7, the arrangement of sensor pads 30 comprises seven rows by six columns on each page face, there are twenty-five sensor pads available for content pads 47. All page face indicator pads 46 except the first and the last may indicate two page faces. If an insert of pages 15 uses the 6 by 7 pad arrangement to the full extent, sixty-six page faces, or thirty-three pages, of content will be available for use by assigning two page faces to each of thirty-two page indicator pads 46, and one page face each to the first and the thirty-fourth. The sixty-six page faces of content each having available twenty-five content icons represent an increase over forty-four page faces each having available twenty content icons.

The arrangements of FIG. 6 and FIG. 7 show a seven row by six column configuration of sensing pads 30 for a total number of forty-two pads, however, other numbers and configurations are possible. Also, pad shape may take other forms than square, for example, rectangular, “H” shaped, circular, or other geometries that come to the mind of the pad designer.

Another exemplary method of indicating page face number may use the fact that pages 15 stacked one on top of another over a sensing pad 30 yields increasing distance from sensing pad 30 as the height of the stack of pages 15 increases. Since E-Field IC 35 may determine approximate distance from electrodes that an object is positioned, E-Field IC 35 may be able to determine the page number chosen by sensing the distance the object is positioned from electrodes 37.

In other aspects of embodiments of the invention, electrodes 37 may be connected to E-Field IC 35 utilizing, for example, coaxial cable, so that sensing pads 30 do not have to be close to E-Field IC 35. E-Field IC 35 may generate a signal on the shield of coaxial cable or on the PCB trace that closely approximates signal conductor voltage as described in Freescale Semiconductor Technical data sheet, “Panel Applications Using MC34940/MC33794 E-Field ICs,” publication number AN1985, Revision 4, November 2006, hereby incorporated herein by reference in its entirety.

In other aspects of embodiments of the invention, digital content 45 may be a database or other content created by a client user who wishes to design accessible digital content 45 for a person to access. For example, a teacher may wish to include more in-depth lesson material for a person accessing more general material via human recognizable content 20. IHPM 5 may be designed so that the teacher may design or modify the digital content 45 accessed by a student who uses the human recognizable content 20 in a process called prescriptive publishing.

In other further aspects of embodiments of the invention, digital content 45 may be a portion of a larger database and use is restricted using a digital right management system. The host device may recognize a signal placed by E-Field IC 35 or an associated electronic device and grant or deny permission to certain content based on the content of the signal.

In other embodiments, it is envisioned that the sensitivity of sensing pads 30 may be tuned. The tuning may vary through a range from low sensitivity, requiring an accurate selection of a sensing pad 30, to high sensitivity, requiring only a rough proximity of the user's finger to sensing pad 30 to select digital content 45. Tuning to a low sensitivity may allow a blind user, who may touch Braille text on page 15 often, to read page 15 without triggering, or innervating, sensing pads 30 accidentally. Conversely, tuning sensing pads 30 to a very high sensitivity may allow a reader who has poor motor function to select digital content 45 by merely bringing a finger or object approximately near, without touching, sensing pad 30. Thus, IHPM 5 may be selectively modified for different abilities of different users.

In other further aspects of embodiments of the invention, sensing pads 30 may be placed on an object displaying human recognizable content 20 in places where a user of content 20 may select various sensing pads 30 to access more in-depth digital content about an area of content 20. For example, sensing pads 30 may be placed at several locations around a globe modeling the planet earth. A user of the globe may use a sensing pad 30 to access digital information from the Internet about a specific country. As with other embodiments, senses other than sight may recognize the human recognizable content. For example, Braille markers on the globe may enable a blind student to use the globe to access digital, audible content. Names or images molded into a plastic globe may also furnish human recognizable content.

In yet further embodiments of the invention, it is envisioned that the number of covers may be less than two or more than two. For example, a clipboard-type device, having an open tablet and no cover, may become a touch panel with sensing pads that a person may use to access digital content. In another example, a back tablet may become a touch panel, while two touch panels of one-half the width of the back cover may hinge, one on each side, to the back cover to create a tri-fold configuration with three panel surfaces. Four covers, each covering one quadrant of a tablet, may also be used. Other configurations may occur to designers of interactive hybrid printed material.

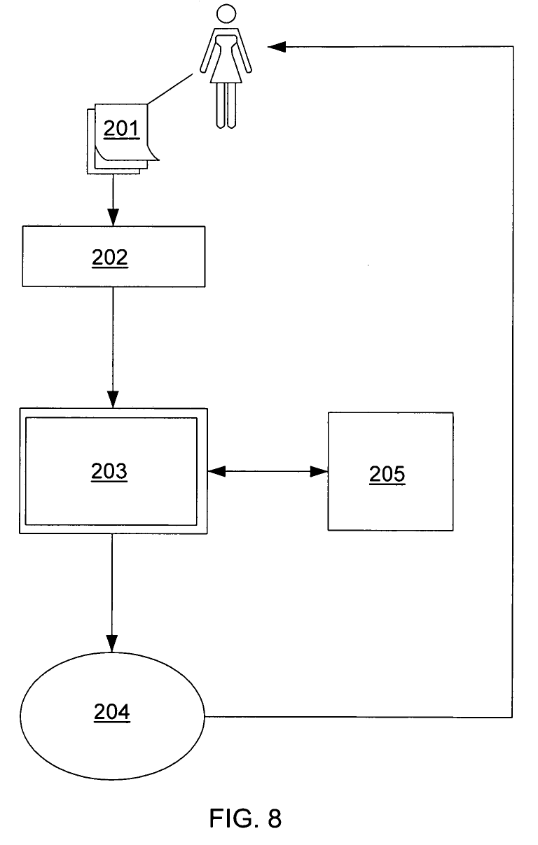

FIG. 8 depicts a system and method for facilitating transactions. In one embodiment, the IHPM 5 may include a TouchBook™ device 201 (by Somatic Digital, Cincinnati, Ohio) that may act as a point of sale (POS) device. For example, a user may use a TouchBook™ device 201 with a page 15 of printed material, and may link to a host device 40, such as computer 202, with hardware components and a linkage database running in a client/server application. The user may choose items to purchase utilizing digital content 45 displayed by computer 202 to the user. TouchBook™ device 201, acting as a POS device, may authenticate and identify the user. This identity and authentication may be established in part or in whole as a result of the presence of 1) hardware platform, 2) printed material, and 3) linkage database in the client/server application. Back office servers 203 may manage receipt of payment by a payment authority 205, such as a bank or other institution, and process the payment to be made to a merchant 204. Merchant 204 may send a product to the user. In another embodiment, payment may be made directly from a payment authority 205 to a merchant 204.

In another embodiment of the transaction system, printed page 15 may contain and/or display advertisement(s). The user may touch a product advertisement that interests the user and is connected to a digital display containing the product. The user may then purchase product after identification. Advertisers may publish printed material compatible with the TouchBook™ device 201 and receive royalties for purchased products. Sales may be recorded and proper royalties tallied by back office servers 203.

While the present invention has been illustrated by description of several embodiments, it is not the intention of the applicant to restrict or limit the spirit and scope of the appended claims to such detail. Numerous other variations, changes, and substitutions will occur to those skilled in the art without departing from the scope of the invention. For instance, while the device and method disclosed herein may be implemented in the education field, it will be understood the present invention has applicability in other fields such as sales demonstrations, technical manuals, game playing, inventory control and others. Moreover, the structure of each element associated with the present invention may be alternatively described as a means for providing the function performed by the element. It will be understood that the foregoing description is provided by way of example, and that other modifications may occur to those skilled in the art without departing from the scope and spirit of the appended Claims.

It should be understood that the systems and methods described herein may be operating on a single computer server device, a networked group of computer servers, or any other networked computer device or computerized device or system of computer devices or computerized devices on which the tools and/or processes of the exemplary embodiments may operate.

The apparatuses, uses, and methods disclosed herein have been described without reference to specific hardware. However, the apparatuses, uses, and methods disclosed herein have been described in a manner sufficient to enable persons of ordinary skill in the art to readily adapt commercially available hardware as may be needed to reduce any of the embodiments of the present invention to practice without undue experimentation.

Following from the above description and invention summaries, it should be apparent to persons of ordinary skill in the art that, while the methods and apparatuses herein described constitute exemplary embodiments of the present invention, it is to be understood that the inventions contained herein are not limited to the above precise embodiments and that changes may be made without departing from the scope of the invention as defined by the claims. Likewise, it is to be understood that the invention is defined by the claims and it is not necessary to meet any or all of the identified advantages or objects of the invention disclosed herein in order to fall within the scope of the claims, since inherent and/or unforeseen advantages of the present invention may exist even though they may not have been explicitly discussed herein.

What is claimed is:

1. A system for utilizing human-recognizable material to interact with digital content, comprising:
a human-recognizable content;
an electric field generating device adapted to generate an electric field;
an electric field emitting device adjacent to the human-recognizable content and in electrical communication with the electric field generating device, the electric field emitting device adapted to emit the electric field; and
a host device configured to output digital content associated with the human-recognizable content, the host device in electrical communication with the electric field generating device, whereby said host device may receive one or more instruction from the electric field generating device.

2. The system of claim 1, further comprising a non-conductive cover component positioned adjacent to the electric field emitting device.

3. The system of claim 1, wherein the human-recognizable content includes a first human-recognizable content associated with a first digital content and a second human-recognizable content associated with a second digital content; and
wherein the first human-recognizable content is replaced by the second human-recognizable content and the host device may be instructed to output the second digital content.

4. The system of claim 1, wherein the human-recognizable content includes at least one of documents, magazines, newspapers, brochures, articles, manuals, books, publications and periodicals.

5. The system of claim 1, wherein the electric field emitting device is adapted to sense an object adjacent to the electric field emitting device.

6. The system of claim 1, wherein the electric field generating device senses a distance from an object to the electric field emitting device.

7. The system of claim 1, wherein the electric field generating device and the electric field emitting device operate as one component.

8. The system of claim 1, wherein the electric field generating device and the electric field emitting device are enclosed within substantially the same physical component.

9. The system of claim 1, wherein the electric field generating device is detachably coupled to the human-recognizable content.

10. The system of claim 1, wherein the electric field emitting device is integrated within the human-recognizable content.

11. The system of claim 1, wherein the human-recognizable content includes at least one of a front cover and a back cover.

12. The system of claim 11, wherein the electric field emitting device is integrated within at least one of the front cover and the back cover of the human-recognizable content.

13. The system of claim 1, wherein the electric field generating device generates an electric current that creates the electric field;
wherein the electric field emitting device is further adapted to sense a change in the electric current to determine that an object is near the electric field emitting device; and
wherein the host device outputs digital content based, at least in part, on the sensed change in the electric current.

14. A method of accessing digital content, the method comprising the steps of:
providing human-recognizable content and one or more digital content associated therewith;
providing one or more electric field generating devices and one or more electric field emitting devices;
generating, by the one or more electric field generating devices, one or more electric fields;
emitting, by the one or more electric field emitting devices, the one or more electric fields adjacent the one or more human recognizable content;
placing an object substantially within at least one of one or more electric fields;
recognizing, by the electric field emitting device, which electric fields are near the placed object; and
retrieving one or more digital content from a database of digital content based, at least in part, on which electric fields are near the placed object.

15. The method of claim 14, further comprising the steps of:
providing a second human-recognizable content and one or more digital content associated therewith;
replacing the human-recognizable content with the second human-recognizable content;
placing the object substantially within at least one of one or more electric fields;
recognizing, by the electric field emitting device, which electric fields are near the placed object; and
retrieving one or more digital content from a second database of digital content based, at least in part, on which electric fields are near the placed object.

16. The method of claim 14, wherein the object is at least one of a human finger, a human hand and an input device.

17. The method of claim 14, wherein the human-recognizable content includes at least one of documents, magazines, newspapers, brochures, articles, manuals, books, publications and periodicals.

18. A system for utilizing human-recognizable material to interact with digital content, comprising:
a panel adapted to receive human-recognizable content thereon; and
a plurality of sensing pads in electrical communication with the panel, the plurality of sensing pads being coupled to the panel;
wherein at least one sensing pad is configured to indicate a page number of the human-recognizable content; and
wherein at least one sensing pad is configured to indicate a digital content associated with the human-recognizable content.

19. The system of claim 18, wherein the plurality of sensing pads are further configured to sense an object near at least one of the sensing pads.

20. The system of claim 18, further comprising:
a cover component located between the panel and the human-recognizable content;
wherein the cover component does not interfere with the operation of the plurality of sensing pads.

21. The system of claim 18, wherein the plurality of sensing pads are arranged on the panel to substantially form a rectangular pattern having a plurality of rows and a plurality of columns; and
wherein the sensing pads configured to indicate a page number of the human-recognizable content are arranged along at least one row or column running along an edge of the panel.
